(19) United States
(12) Patent Application Publication
(10) Pub. No.: US 2024/0421810 A1
(43) Pub. Date: Dec. 19, 2024

(54) ADAPTIVE RINGING CLAMP

(71) Applicant: TEXAS INSTRUMENTS INCORPORATED, Dallas, TX (US)

(72) Inventors: Saqib SATTI, Freising (DE); Qiao YANG, Muenchen (DE); Stefan HERZER, Marzling (DE)

(21) Appl. No.: 18/337,096

(22) Filed: Jun. 19, 2023

(51) Int. Cl. H03K 17/0412; H03K 17/16

(52) U.S. Cl. CPC H03K 17/04123; H03K 17/162; H03K 2217/0063; H03K 2217/0072

(57) ABSTRACT

A circuit includes a first transistor and a ringing control circuit. The first transistor is coupled between a power terminal and a switching terminal. The first transistor includes a first control terminal. The ringing control circuit is coupled between the power terminal and the first control terminal. The ringing control circuit includes a second transistor and a variable resistance circuit. The second transistor is coupled between the power terminal and the first control terminal. The second transistor has a second control terminal. The variable resistance circuit is coupled between the second control terminal and the switching terminal. The variable resistance circuit includes a control input coupled to the power terminal.

### BACKGROUND

A DC-DC converter is an electronic circuit that converts an input direct current (DC) voltage into one or more DC output voltages that are higher or lower in magnitude than the input DC voltage. A DC-DC converter that generates an output voltage lower than the input voltage is termed a buck or step-down converter. A DC-DC converter that generates an output voltage higher than the input voltage is termed a boost or step-up converter.

Some DC-DC converter topologies include a drive/power switch coupled at a switch node to an energy storage inductor/transformer. Electrical energy is transferred through the energy storage inductor/transformer to a load by alternately opening and closing the switch as a function of a switching signal. The amount of electrical energy transferred to the load is a function of the ON/OFF duty cycle of the switch and the frequency of the switching signal. DC-DC converters are widely used in electronic devices, particularly battery powered devices, such as portable cellular phones, laptop computers, and other electronic systems in which efficient use of power is desirable.

### SUMMARY

In one example, a circuit includes a first transistor and a ringing control circuit. The first transistor is coupled between a power terminal and a switching terminal. The first transistor includes a first control terminal. The ringing control circuit is coupled between the power terminal and the first control terminal. The ringing control circuit includes a second transistor and a variable resistance circuit. The second transistor is coupled between the power terminal and the first control terminal. The second transistor has a second control terminal. The variable resistance circuit is coupled between the second control terminal and the switching terminal. The variable resistance circuit includes a control input coupled to the power terminal.

In another example, a circuit includes a first transistor and a ringing control circuit. The first transistor is coupled between a power terminal and a switching terminal. The first transistor includes a first control terminal. The ringing control circuit is coupled between the power terminal and the first control terminal. The ringing control circuit is configured to clamp a voltage at the power terminal at a first voltage based on a second voltage at the power terminal, and clamp a voltage at the power terminal at a third voltage based on a fourth voltage at the power terminal.

In a further example, a circuit includes a high-side transistor, a low-side transistor, a high-side driver, a low-side driver, and a high-side ringing control circuit. The high-side transistor is coupled between a power terminal and a switching terminal. The high-side transistor includes a high-side control terminal. The low-side transistor is coupled between the switching terminal and a ground terminal. The low-side transistor includes a low-side control terminal. The high-side driver has a first driver input and a first driver output. The first driver input is coupled to a first PWM terminal and the first driver output is coupled to the high-side control terminal. The low-side driver has a second driver input and a second driver output. The second driver input is coupled to a second PWM terminal and the second driver output is coupled to the low-side control terminal. The high-side ringing control circuit is coupled between the power terminal and the high-side control terminal. The high-side ringing control circuit includes a first transistor and a variable resistance circuit. The first transistor is coupled between the power terminal and the high-side control terminal. The first transistor has a first control terminal. The variable resistance circuit is coupled between the first control terminal and the switching terminal. The variable resistance circuit includes a second transistor having a second control terminal coupled to the power terminal. The second transistor is coupled between the first control terminal and the switching terminal.

### BRIEF DESCRIPTION OF THE DRAWINGS

FIG. 1 is a schematic of an example DC-DC converter circuit that includes ringing control circuits.

FIG. 2 is a schematic of an example ringing control circuit that can be part of the DC-DC converter circuit of FIG. 1.

FIGS. 3, 4, and 5 are schematics of example high-side ringing control circuits that can be part of the DC-DC convert circuit of FIG. 1.

FIG. 6 is a schematic of an example low-side ringing control circuit that can be part of the DC-DC convert circuit of FIG. 1.

FIG. 7 is a graph of example overshoot in the DC-DC converter of FIG. 1 with various input voltages using the ringing control circuits of FIG. 3, 4, or 5.

FIG. 8 is a graph of example signals illustrating operation of ringing control circuits in the DC-DC converter of FIG. 1.

The same reference numbers or other reference designators are used in the drawings to designate the same or similar (either by function and/or structure) features.

### DETAILED DESCRIPTION

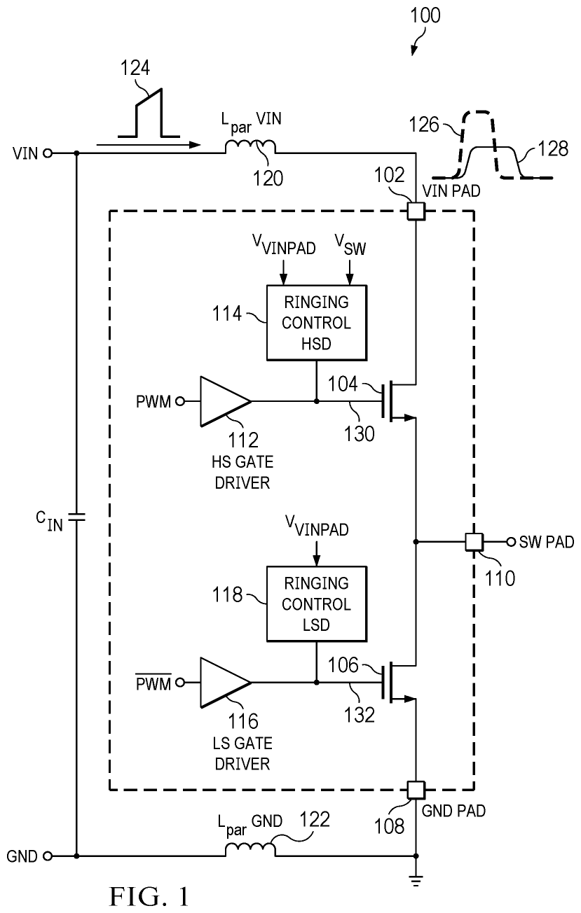

FIG. 1 is a schematic of an example DC-DC converter circuit 100. The DC-DC converter circuit 100 includes a power terminal 102, a high-side transistor 104, a low-side transistor 106, a ground terminal 108, a switching terminal 110, a high-side driver 112, a high-side ringing control circuit 114, a low-side driver 116, and a low-side ringing control circuit 118. The DC-DC converter circuit 100 is illustrated as a step-down (buck) converter, but some examples of the DC-DC converter circuit 100 can be a different type of converter (e.g., a buck-boost converter). The high-side driver 112 controls switching of the high-side transistor 104, and the low-side driver 116 controls switching of the low-side transistor 106. A driver input of the high-side driver 112 is coupled to a first output of a pulse width modulation (PWM) circuit (not shown) or a first PWM terminal, and a driver output of the high-side driver 112 is coupled to a high-side control terminal (e.g., gate) of the high-side transistor 104. A driver input of the low-side driver 116 is coupled to a second output of the PWM circuit or a second PWM terminal, and a driver output of the low-side driver 116 is coupled to a low-side control terminal (e.g., gate) of the low-side transistor 106. The high-side transistor 104 and the low-side transistor 106 can be n-channel field effect transistors (NFETs).

A first current terminal (e.g., drain) of the high-side transistor 104 is coupled to the power terminal 102. A second current terminal (e.g., source) of the high-side transistor 104 is coupled to the switching terminal 110. A first current terminal of the low-side transistor 106 (e.g., drain) is coupled to the switching terminal 110. A second current terminal (e.g., source) of the low-side transistor 106 is coupled to the ground terminal 108. An inductor (not shown) can be coupled to the switching terminal 110 for charging and discharging by switching of the high-side transistor 104 and the low-side transistor 106. The high-side driver 112 turns on the high-side transistor 104 and the low-side driver 116 turns off the low-side transistor 106 to charge the inductor coupled to the switching terminal 110. The low-side driver 116 turns on the low-side transistor 106 and the high-side driver 112 turns off the high-side transistor 104 to discharge the inductor coupled to the switching terminal 110.

Conductors (e.g., printed circuit board traces, bond wires, etc.) coupled to the power terminal 102 can include a parasitic inductance 120, and conductors coupled to the ground terminal 108 can include a parasitic inductance 122. The switching of the high-side transistor 104 and the low-side transistor 106 charges and discharges these parasitic inductances. When the high-side transistor 104 is turned off and the low-side transistor 106 is turned on, current flow through the power terminal 102 stops abruptly, and the voltage at the power terminal 102 increases and generates an overshoot 126. The magnitude of the overshoot 126 can be based on parasitic inductance 120 and the rate of change of the current flow

$$( V = L \frac{di}{dt} ) .$$

The overshoot 126 can cause the voltage across the high-side transistor 104 to exceed a maximum safe operating voltage. The low-side transistor 106 is subject to similar overshoot (and potential damage) when the low-side transistor 106 is turned off. The voltage stress can damage or otherwise reduce the lifetime of the high-side transistor 104 and the low-side transistor 106, and degrade the reliability of the DC-DC converter circuit 100.

The high-side ringing control circuit 114 senses overshoot at the power terminal 102 and delays the turn-off of the high-side transistor 104 to reduce the amplitude of the overshoot, represented by the clamped overshoot 128 of FIG. 1. The high-side ringing control circuit 114 can include a first control input coupled to the power terminal 102, a second control input coupled to the switching terminal 110, and a control output coupled to the control terminal of the high-side transistor 104. The high-side ringing control circuit 114 receives the voltages at the power terminal 102 and the switching terminal 110, and provides an output signal 130 that delays the turn-off the high-side transistor 104. Accordingly, a current path through the high-side transistor 104 and the low-side transistor 106 can be enabled to discharge the power terminal 102 and reduce the amplitude of the overshoot.

Similarly, the low-side ringing control circuit 118 senses an increase in voltage across the low-side transistor 106 (or an increase in the voltage on the power terminal 102) and provides an output signal 132 that turns on the low-side transistor 106 to reduce the amplitude of transient voltage across the low-side transistor 106. The low-side ringing control circuit 118 includes a control input coupled to the power terminal 102 and a control output coupled to the control terminal of the low-side transistor 106. The low-side ringing control circuit 118 receives the voltage at the power terminal 102, and provides, based on the voltage, the output signal 132 that turns-on the low-side transistor 106. Accordingly, a current path through the high-side transistor 104 and the low-side transistor 106 can be enabled to discharge the power terminal 102 and reduce the amplitude of the overshoot.

The ringing control circuits 114 and 118 can delay the turn off the respective high-side transistor 104 and low-side transistor 106 to provide a current path to discharge the power terminal 102, which can reduce the overshoot and the voltage across the respective high-side transistor 104 and low-side transistor 106 caused by the overshoot. Such arrangements can reduce the voltage stress on the high-side transistor 104 and low-side transistor 106 due to the overshoot and improve reliability. Also, the DC-DC converter circuit 100 does not need to include a separate device to provide the current path to discharge the power terminal 102, which can reduce the footprint of the DC-DC converter circuit 100.

In some ringing control circuits, the clamping is configured based on worst case operational conditions (e.g., maximum operating voltage Vin at the power terminal 102 and maximum load current). Clamping based on worst case operational conditions protects the high-side transistor 104 under a wide range of operational conditions, but can reduce the performance of the DC-DC converter circuit 100 if Vin is less than the maximum operating voltage. With lower values of Vin, higher overshoot voltage, relative to Vin, can be tolerated without risking damage to the high-side transistor 104, and allowing higher overshoot can reduce current commutation time and improve efficiency in the DC-DC converter circuit 100. Examples of the high-side ringing control circuit 114 can control clamping (clamp strength) based on Vin. The high-side ringing control circuit 114 can provide stronger clamping for higher values of Vin and tolerate a lower overshoot voltage relative to Vin, and provide weaker clamping for lower values of Vin and tolerate a higher overshoot voltage relative to Vin. Accordingly, the high-side ringing control circuit 114 can protect the high-side transistor 104 from damage due to overshoot over the entire Vin operating range (including maximum Vin), while increasing efficiency with lower values on Vin.

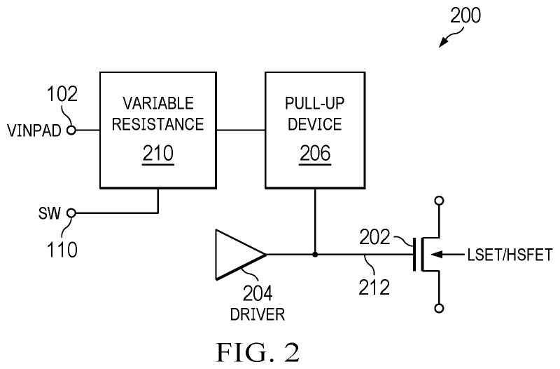

FIG. 2 is a schematic of an example ringing control circuit 200 that can be part of the DC-DC converter circuit 100. The ringing control circuit 200 can be part of the high-side ringing control circuit 114. The ringing control circuit 200 can also be part of the low-side ringing control circuit 118. The transistor 202 can be the high-side transistor 104 or the low-side transistor 106 of the DC-DC converter circuit 100. The driver 204 can be the high-side driver 112 or the low-side driver 116 of the DC-DC converter circuit 100. The pull-up device 206 is coupled between a control terminal (e.g., gate) of the transistor 202 and a pull-up voltage source, such as the power terminal 102 or other voltage source). The pull-up device 206 provides a current at an output to pull-up the control terminal voltage of the transistor 202 and turns on (or delays the turn-off of) the transistor 202.

A variable resistance circuit 210 is coupled between the power terminal 102 and the switching terminal 110, and between the power terminal 102 and the control terminal of the 202. A transient (e.g., an overshoot) on the power terminal 102 caused by turning off the high-side transistor 104) triggers turn-on of the pull-up device 206, and the pull-up device 206 provides a current to the control terminal of the transistor 202. The current provided by the pull-up device 206 turns on (or delays the turn-off of) the transistor 202 to reduce the voltage across the transistor 202. The resistance of the variable resistance circuit 210 controls the current provided by the pull-up device 206. The resistance of the variable resistance circuit 210 varies based on the value Vin at the power terminal 102. The resistance of the variable resistance circuit 210 is higher with a higher value of Vin, and lower with a lower value of Vin. Higher resistance of the variable resistance circuit 210 increases the current provided by the pull-up device 206 to increase clamp strength. Lower resistance of the variable resistance circuit 210 decreases the current provided by the pull-up device 206 to decrease clamp strength. Accordingly, the ringing control circuit 200 provides lower clamp strength with lower values of Vin and higher clamp strength with higher values of Vin. The lower clamp strength allows for higher efficiency at lower values of Vin.

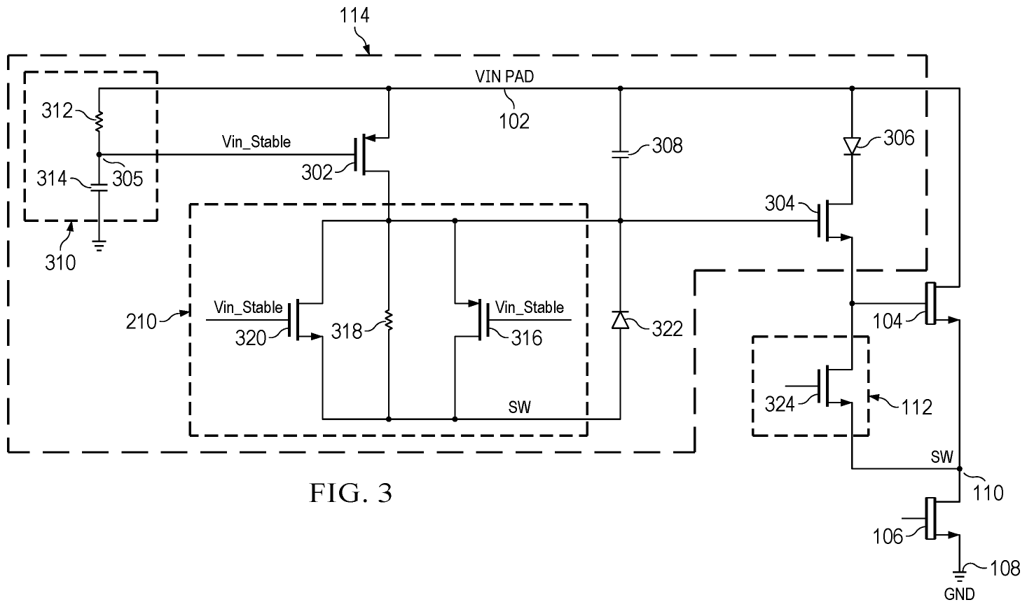

FIG. 3 is a schematic of example internal components of an example high-side ringing control circuit 114. The high-side ringing control circuit 114 includes a transistor 302, a transistor 304, a diode 306, a capacitor 308, a low-pass filter circuit 310, the variable resistance circuit 210, and a diode 322. The low-pass filter circuit 310 includes a resistor 312 and a capacitor 314. The example of the variable resistance circuit 210 shown in FIG. 3 includes a transistor 316, a resistor 318, and a transistor 320. The transistor 304 and the transistor 320 can be NFETs. The transistor 302 and the transistor 316 can be p-channel field effect transistors (PFETs). The high-side transistor 104, the low-side transistor 106, and a portion (the pull-down transistor 324) of the a high-side driver 112 are shown in FIG. 3 for reference. Resistor 318 can include various types of resistors, such as polysilicon resistors, diffused resistors, ion-implanted resistors, and thin-film resistors. In some examples, resistor 318 can be implemented using a transistor biased in triode/ohmic region, such as a PFET having a gate/control terminal coupled to ground.

The transistor 304 is coupled between the power terminal 102 and the control terminal of the high-side transistor 104. The transistor 304 can be an example of the pull-up device 206 (FIG. 2). The high-side transistor 104 can be turned off by turning on the pull-down transistor 324. Current flowing through the transistor 304 can charge and increase the voltage of the control terminal of the high-side transistor 104, which can delay the turn-off of the high-side transistor 104. A first current terminal (e.g., drain) of the transistor 304 is coupled to the power terminal 102 via the diode 306. The diode 306 blocks flow of current from the transistor 304 to the power terminal 102. A second current terminal (e.g., source) of the transistor 304 is coupled to the control terminal of the high-side transistor 104. In some examples, the diode 306 can be coupled between the transistor 304 and the high-side transistor 104.

The capacitor 308 and the variable resistance circuit 210 form a high-pass filter coupled between the power terminal 102 and the control terminal (e.g., gate) of the transistor 304. The capacitor 308 is coupled between the power terminal 102 and the control terminal of the transistor 304. The variable resistance circuit 210 is coupled between the control terminal of the transistor 304 and the switching terminal 110. When the high-side transistor 104 starts to turn off, and the voltage on the power terminal 102 rises, the transient on the power terminal 102 passes through the capacitor 308 to turn on the transistor 304, which can connect the control terminal of the high-side transistor 104 to the power terminal 102 and increase the control terminal voltage of the high-side transistor 104. The increased control terminal voltage can delay the turn-off of the high-side transistor 104.

The diode 322 limits the voltage at the control terminal of the transistor 304. A cathode of the diode 322 is coupled to the control terminal of the transistor 304. An anode of the diode 322 is coupled to the switching terminal 110.

The capacitor 314 and the resistor 312 form a low-pass filter (e.g., the low-pass filter circuit 310) coupled between the power terminal 102 and the ground terminal 108. The low-pass filter circuit 310 provides a stable (lacking ringing and other transients) version of Vin (Vin_Stable) at the node 305 (the filter output) connecting the resistor 312 and the capacitor 314.

The transistor 302 is coupled between the power terminal 102 and the control terminal of the transistor 304. The control terminal (e.g., gate) of the transistor 302 is coupled to the node 305. The transistor 302 switches current to the control terminal of the transistor 304 responsive to overshoot on the power terminal 102. A first current terminal (e.g., source) of the transistor 302 is coupled to the power terminal 102, and a second current terminal (e.g., drain) of the transistor 302 is coupled to the control terminal of the transistor 304.

When the voltage on the power terminal 102 starts to rise, as the high-side transistor 104 is turned off and the low-side transistor 106 is turned on, the transistor 302 turns on and current flows through the transistor 302. The transistor 302 can connect power terminal 102 to the control terminal of the transistor 304 to increase the control terminal voltage of the transistor 304, which can delay the turn off of the high-side transistor 104. When no overshoot is present on Vin, the transistor 302 can be turned off.

The variable resistance circuit 210 is coupled between the transistor 302 and the switching terminal 110. The current flowing through the transistor 302 flows through the variable resistance circuit 210, and the voltage developed across the variable resistance circuit 210 due to the current can set a gate voltage of the transistor 304. The gate voltage can reflect the clamping strength, with a higher gate voltage providing a higher clamping strength and a lower gate voltage providing a lower/reduced clamping strength. The gate voltage can also be set by the resistance of the variable resistance circuit 210, where a lower resistance can provide a lower gate voltage and a higher resistance can provide a higher gate voltage.

The example of the variable resistance circuit 210 shown in FIG. 3, includes the transistor 316, the resistor 318, and the transistor 320 coupled in parallel between the switching terminal 110 and the second current terminal of the transistor 302. A first current terminal (e.g., drain) of the transistor 320, a first terminal of the resistor 318, and a first current terminal (e.g., source) of the transistor 316 are coupled to the second current terminal (e.g., drain) of the transistor 302. A second current terminal (e.g., source) of the transistor 320, a second terminal of the resistor 318, and a second current terminal (e.g., drain) of the transistor 316 are coupled to the switching terminal 110. The control terminals (e.g., gates) of the transistor 316 and the transistor 320 are coupled to the node 305. The transistor 316 and the transistor 320 operate as variable resistors with a resistance based on the voltage at the node 305 (Vin_Stable). For example, the resistance of the transistor 316 increases with Vin_Stable, and the resistance of the transistor 320 decreases with Vin_Stable. Accordingly, for a high Vin_Stable, the transistor 316 can be disabled or have a much higher resistance than the transistor 320 and the resistor 318, and the overall resistance of the variable resistance circuit 210 can be dominated by a parallel combination of the transistor 320 and the resistor 318. Also, for a low Vin_Stable, the transistor 320 can be disabled or have a much higher resistance than the transistor 316 and the resistor 318, and the overall resistance of the variable resistance circuit 210 can be dominated by a parallel combination of the transistor 316 and the resistor 318.

With the arrangements of FIG. 3, the variable resistance circuit 210 can provide a relatively high resistance and a relatively high gate voltage for high Vin_Stable, and provide a relatively low resistance and a relatively low gate voltage for low Vin_Stable. Accordingly, the variation in resistance of the variable resistance circuit 210 based on Vin_Stable causes the high-side ringing control circuit 114 to provide higher clamping strength (a higher gate voltage of the transistor 304, which allows a higher current through the transistor 304) with higher Vin, and lower clamping strength (a lower gate voltage of the transistor 304, which allows a lower current through the transistor 304) with lower Vin, which protects the high-side transistor 104 and improves efficiency when Vin is lower.

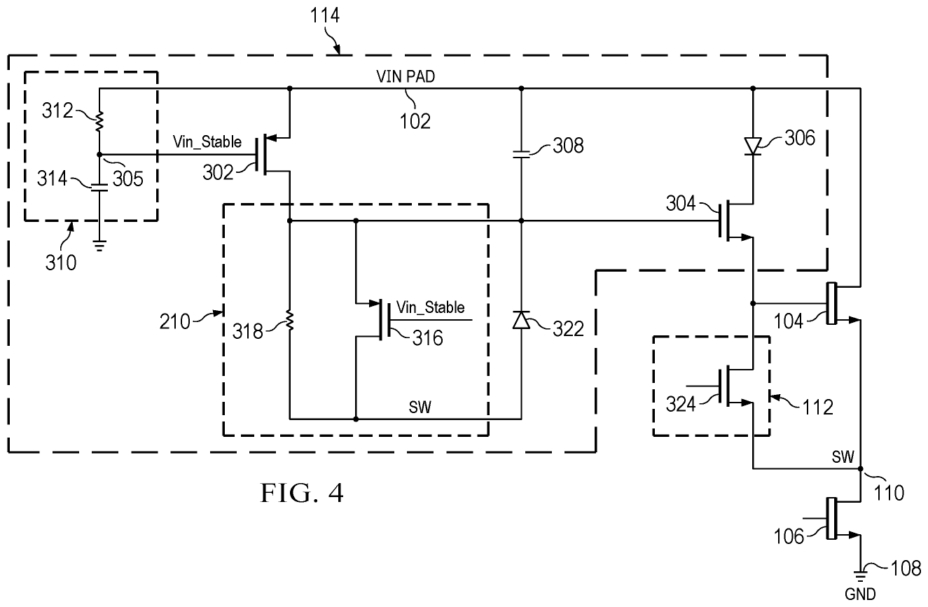

FIG. 4 is a schematic of another example high-side ringing control circuit 114 that can be used in the DC-DC converter circuit 100. The high-side ringing control circuit 114 of FIG. 4 includes the includes the transistor 302, the transistor 304, the diode 306, the capacitor 308, the low-pass filter circuit 310, and the diode 322 as described per FIG. 3. The high-side ringing control circuit 114 of FIG. 4 also includes an example of the variable resistance circuit 210 that differs from that of FIG. 3. In FIG. 4, the variable resistance circuit 210 includes the transistor 316 and the resistor 318, but lacks the transistor 320 shown in FIG. 3. The operation of the variable resistance circuit 210 in FIG. 4 is generally similar to that of the variable resistance circuit 210 of FIG. 3. The resistance of the transistor 316 is higher (e.g., hundreds of megaohms or giga-ohms) with higher Vin and the resistance of the transistor 316 is lower with lower Vin. Accordingly, the resistance of the variable resistance circuit 210 is higher with higher Vin_Stable and lower with lower Vin_Stable. The variation in resistance of the variable resistance circuit 210 based on Vin_Stable causes the high-side ringing control circuit 114 to provide higher clamping strength with higher Vin and lower clamping strength with lower Vin, which protects the high-side transistor 104 and improves efficiency when Vin is lower.

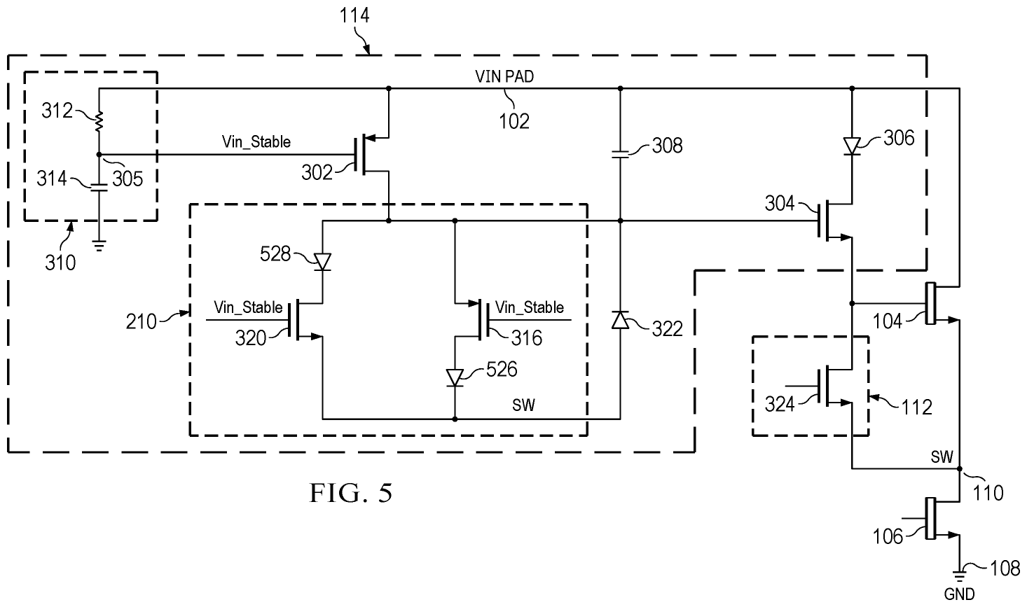

FIG. 5 is a schematic of another example high-side ringing control circuit 114 that can be used in the DC-DC converter circuit 100. The high-side ringing control circuit 114 of FIG. 5 includes the includes the transistor 302, the transistor 304, the diode 306, the capacitor 308, the low-pass filter circuit 310, and the diode 322 as described per FIG. 3. The high-side ringing control circuit 114 of FIG. 5 also includes an example of the variable resistance circuit 210 that differs from that of FIG. 3. In FIG. 5, the variable resistance circuit 210 includes the transistor 316 and the transistor 320, but lacks the resistor 318 shown in FIG. 3. The operation of the variable resistance circuit 210 in FIG. 4 is generally similar to that of the variable resistance circuit 210 of FIG. 3. The resistance of the transistor 316 is higher (e.g., hundreds of megaohms) with higher Vin and the resistance of the transistor 316 is lower with lower Vin. The resistance of the transistor 320 is higher (e.g., hundreds of megaohms) with lower Vin and the resistance of the transistor 320 is higher with lower Vin. Accordingly, the resistance of the variable resistance circuit 210 is higher with higher Vin_Stable and lower with lower Vin_Stable. The variation in resistance of the variable resistance circuit 210 based on Vin_Stable causes the high-side ringing control circuit 114 to provide higher clamping strength with higher Vin and lower clamping strength with lower Vin, which protects the high-side transistor 104 and improves efficiency when Vin is lower.

Some examples of variable resistance circuit 210, including the variable resistance circuit 210 shown in FIG. 3, 4, or 5 can also optionally include a diode 526 in series with the transistor 316, and/or a diode 528 in series with the transistor 320. The diode 526 and/or the diode 528 can reduce the drain-to-source voltage of the transistor 316 and/or the transistor 320 and provide protection if the voltage at the control terminal of the transistor 304 exceeds the safe operating voltage of the transistor 316 and/or the transistor 320 due to overshoot on Vin.

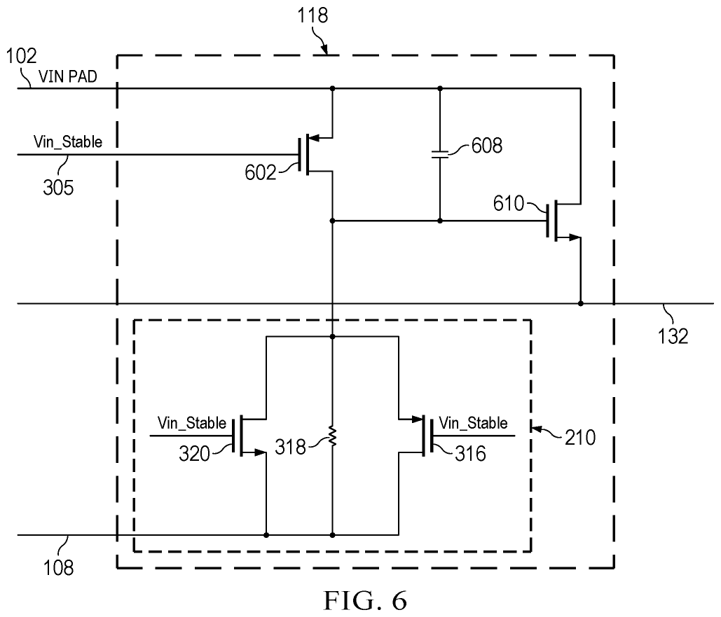

FIG. 6 is a schematic of an example low-side ringing control circuit 118. The low-side ringing control circuit 118 includes a transistor 602, a capacitor 608, a transistor 610, and the variable resistance circuit 210. The transistor 610 is coupled between the power terminal 102 and the control terminal of the low-side transistor 106. The transistor 610 can be an NFET. A first current terminal (e.g., drain) of the transistor 610 is coupled to the power terminal 102, and a second current terminal (e.g., source) of the transistor 610 is coupled to the control terminal of the low-side transistor 106. The capacitor 608 and the variable resistance circuit 210 form a high-pass filter. The capacitor 608 is coupled between the power terminal 102 and the control terminal of the transistor 610. In some examples, the capacitor 608 can be coupled between the switching terminal 110 and the control terminal of the transistor 610. The variable resistance circuit 210 is coupled between the ground terminal 108 and the control terminal of the transistor 610. When the voltage on the power terminal 102 rises, the transient on the power terminal 102 passes through the capacitor 608 to turn on the transistor 610. The transistor 610 conducts current from the power terminal 102 to charge up and raise the voltage of the control terminal of the low-side transistor 106, which turns on the low-side transistor 106.

The transistor 602 is coupled between the power terminal 102 and the control terminal of the transistor 610. The transistor 602 can be a PFET. A first current terminal (e.g., source) of the transistor 602 is coupled to the power terminal 102, and a second current terminal (e.g., drain) of the transistor 602 is coupled to the control terminal of the transistor 610. A control terminal (e.g., gate) of the transistor 602 is coupled to a DC bias source or voltage reference. In some examples, that DC bias source/voltage reference can be provided by the node 305 of FIG. 3.

As the voltage on the power terminal 102 increases, and a stable voltage reference is provided at the control terminal of the transistor 502, the source-gate voltage of the transistor 602 increases, and the transistor 602 turns on. Current flowing through the transistor 602 produces a voltage across the variable resistance circuit 210 that turns on the transistor 610 and delays the turn off of (or turns on) the low-side transistor 106. The voltage across the variable resistance circuit 210 is a function of the resistance of the variable resistance circuit 210. The variable resistance circuit 210 used in the low-side ringing control circuit 118 can be the same as the variable resistance circuit 210 shown in FIG. 3, 4, or 5. As explained above, the resistance of the variable resistance circuit 210 increases with Vin (Vin_Stable), which causes the current flowing through the transistor 610 to increase with Vin, and provide stronger clamping with higher Vin and weaker clamping with lower Vin.

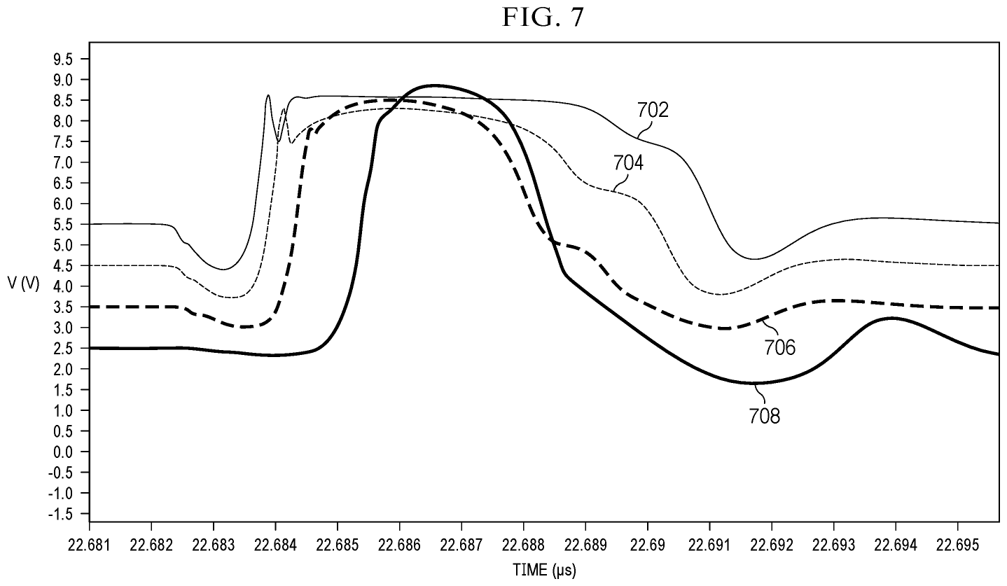

FIG. 7 is a graph of example overshoot in the DC-DC converter circuit 100 with various input voltages using the ringing control circuits of FIG. 3, 4, or 5. In FIG. 7, the high-side transistor 104 is being turned off and the low-side transistor 106 is being turned on, which produces an overshoot on Vin. The high-side ringing control circuit 114 clamps Vin to prevent damage to the high-side transistor 104. In the example of FIG. 7, the high-side ringing control circuit 114 clamps Vin 702 of about 5.5 volts to about 8.5 volts (about 3 volts of overshoot). The high-side ringing control circuit 114 clamps Vin 704 of about 4.5 volts to about 8.25 volts (about 3.75 volts of overshoot). The high-side ringing control circuit 114 clamps Vin 706 of about 3.5 volts to about 8.5 volts (about 5 volts of overshoot). The high-side ringing control circuit 114 clamps Vin 708 of about 2.5 volts to about 8.75 volts (about 6.25 volts of overshoot). Thus, the high-side ringing control circuit 114 allows more overshoot, relative to Vin, with lower values of Vin than with higher values of Vin, which improves the efficiency of the DC-DC converter circuit 100 with lower values of Vin.

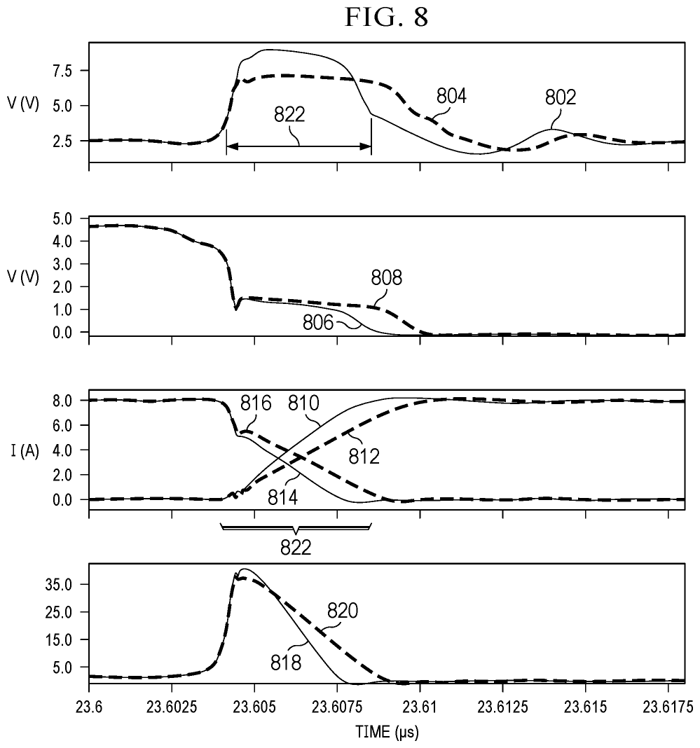

FIG. 8 is a graph of example signals illustrating operation of the high-side ringing control circuit 114 in the DC-DC converter circuit 100. In FIG. 8, the signals 802 and 804 represent Vin of 2.5 volts and overshoot thereon, with the high-side ringing control circuit 114 and with a fixed voltage clamp circuit, respectively. The signals 806 and 808 represent the voltage at the control terminal of the high-side transistor 104 as the high-side transistor 104 is being turned off, with the high-side ringing control circuit 114 and with a fixed voltage clamp circuit, respectively. The signals 810 and 812 represent the current flowing in the low-side transistor 106 with the high-side ringing control circuit 114 and with a fixed voltage clamp circuit, respectively. The signals 814 and 816 represent the current flowing in the high-side transistor 104 with the high-side ringing control circuit 114 and with a fixed voltage clamp circuit, respectively. The signals 818 and 820 represent the power dissipated in the high-side transistor 104 with the high-side ringing control circuit 114 and with a fixed voltage clamp circuit, respectively.

In FIG. 8, the fixed voltage clamp circuit clamps Vin about 2 volts lower than the high-side ringing control circuit 114 as shown by the signals 802 and 804. The higher clamping voltage of the high-side ringing control circuit 114 reduces the current commutation time 822 relative to a DC-DC converter using a fixed voltage clamp circuit. The signals 806 and 808 show that the drive signal provided at the control terminal of the high-side transistor 104 delays turn-off of the high-side transistor 104 longer with the fixed voltage clamp than with the high-side ringing control circuit 114.

The signals 810-816 show that the switching time (current commutation time) of the high-side transistor 104 and the low-side transistor 106 using the high-side ringing control circuit 114 (and allowing higher overshoot on Vin) is shorter than the switching time using a fixed voltage clamp circuit.

The signals 818 and 820 show that the average power dissipated across the high-side transistor 104 is lower using the high-side ringing control circuit 114 than with a fixed voltage clamp circuit. Accordingly, the efficiency of the DC-DC converter circuit 100 is higher using the high-side ringing control circuit 114 than with a fixed voltage clamp circuit.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) (n-type transistor) or a p-channel FET (PFET)) (p-type transistor)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input (or transistor control terminal) is the gate, and the current terminals are the drain and source. In the context of a BJT, the control input is the base, and the current terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A circuit, comprising:
a first transistor coupled between a power terminal and a switching terminal, the first transistor including a first control terminal; and
a ringing control circuit coupled between the power terminal and the first control terminal, the ringing control circuit including:
a second transistor coupled between the power terminal and the first control terminal, the second transistor having a second control terminal; and
a variable resistance circuit coupled between the second control terminal and the switching terminal, the variable resistance circuit including a control input coupled to the power terminal.

2. The circuit of claim 1, wherein:
the variable resistance circuit includes a third transistor having a third control terminal;
the third transistor is coupled between the second control terminal and the switching terminal; and
the third control terminal is coupled to the power terminal.

3. The circuit of claim 2, wherein the third transistor is p-channel field effect transistor.

4. The circuit of claim 2, wherein the variable resistance circuit includes a resistor, or a fourth transistor biased in a linear region, coupled between the second control terminal and the switching terminal.

5. The circuit of claim 2, wherein:
the variable resistance circuit includes a fourth transistor having a fourth control terminal;
the fourth transistor is coupled between the second control terminal and the switching terminal; and
the fourth control terminal is coupled to the third control terminal.

6. The circuit of claim 5, wherein the fourth transistor is an n-channel field effect transistor.

7. The circuit of claim 2, wherein the ringing control circuit includes a fourth transistor coupled between the power terminal and the second control terminal, the fourth transistor having a fourth control terminal coupled to the power terminal.

8. The circuit of claim 7, wherein the ringing control circuit includes:
a resistor coupled between the power terminal and the fourth control terminal; and
a capacitor coupled between the fourth control terminal and a ground terminal.

9. The circuit of claim 7, wherein the fourth control terminal is coupled to the third control terminal.

10. The circuit of claim 1, wherein the ringing control circuit includes a capacitor coupled between the power terminal and the second control terminal.

11. A circuit comprising:
a first transistor coupled between a power terminal and a switching terminal, the first transistor including a first control terminal; and
a ringing control circuit coupled between the power terminal and the first control terminal, the ringing control circuit configured to:
clamp a voltage at the power terminal at a first voltage based on a second voltage at the power terminal; and
clamp a voltage at the power terminal at a third voltage based on a fourth voltage at the power terminal.

12. The circuit of claim 11, wherein the ringing control circuit includes:
a second transistor having a second control terminal, the second transistor coupled between the power terminal and the first control terminal; and
a variable resistance circuit coupled between the switching terminal and the second control terminal, the variable resistance circuit configured to:
provide a first resistance between the second control terminal and the switching terminal responsive to the second voltage; and
provide a second resistance, that is lower than the first resistance, between the second control terminal and the switching terminal responsive to the fourth voltage.

13. The circuit of claim 12, wherein:
the ringing control circuit includes a low-pass filter circuit having a filter output, the low-pass filter circuit configured to filter a voltage at the power terminal; and
the variable resistance circuit includes a third transistor having a third control terminal coupled to the filter output, the third transistor coupled between the second control terminal and the switching terminal; and
the third transistor is configured to provide a lower resistance with the fourth voltage than with the second voltage.

14. The circuit of claim 13, wherein the variable resistance circuit includes a resistor, or a fourth transistor biased in a linear region, coupled between the second control terminal and the switching terminal.

15. The circuit of claim 13, wherein:
the variable resistance circuit includes a fourth transistor having a fourth control terminal coupled to the filter output, the fourth transistor coupled between the second control terminal and the switching terminal; and
the fourth transistor is configured provide a higher resistance with the fourth voltage than with the second voltage.

16. The circuit of claim 11, wherein the first voltage is lower than the third voltage.

17. A circuit, comprising:
a high-side transistor coupled between a power terminal and a switching terminal, the high-side transistor including a high-side control terminal;
a low-side transistor coupled between the switching terminal and a ground terminal, the low-side transistor including a low-side control terminal;
a high-side driver having a first driver input and a first driver output, in which the first driver input is coupled to a first PWM terminal and the first driver output is coupled to the high-side control terminal;
a low-side driver having a second driver input and a second driver output, in which the second driver input is coupled to a second PWM terminal and the second driver output is coupled to the low-side control terminal;
a high-side ringing control circuit coupled between the power terminal and the high-side control terminal, the high-side ringing control circuit including:
a first transistor coupled between the power terminal and the high-side control terminal, the first transistor having a first control terminal; and
a variable resistance circuit coupled between the first control terminal and the switching terminal, the variable resistance circuit including a second transistor having a second control terminal coupled to the power terminal, the second transistor coupled between the first control terminal and the switching terminal.

18. The circuit of claim 17, wherein the variable resistance circuit includes a resistor coupled between the first control terminal and the switching terminal.

19. The circuit of claim 17, wherein:
the variable resistance circuit includes a third transistor having a third control terminal;
the third transistor is coupled between the first control terminal and the switching terminal; and
the third control terminal is coupled to the second control terminal.

20. The circuit of claim 17, wherein the high-side ringing control circuit includes:
a resistor coupled between the power terminal and the second control terminal; and
a capacitor coupled between the second control terminal and the ground terminal.

21. The circuit of claim 17, wherein the high-side ringing control circuit includes a third transistor coupled between the power terminal and the first control terminal, the third transistor having a third control terminal coupled to the second control terminal.
